(19) United States
(12) Patent Application Publication
(10) Pub. No.: US 2013/0120918 A1
(43) Pub. Date: May 16, 2013

(54) MOUNTING APPARATUS FOR PCI CARD

(71) Applicants: TING-TING HE, Wuhan City (CN); ZHI-PING WU, Wuhan City (CN); XIAO-LI ZHANG, Wuhan City (CN)

(72) Inventors: TING-TING HE, Wuhan City (CN); ZHI-PING WU, Wuhan City (CN); XIAO-LI ZHANG, Wuhan City (CN)

(73) Assignees: HON HAI PRECISION INDUSTRY CO., LTD., Tu-Cheng (TW); HONG FU JIN PRECISION INDUSTRY (WUHAN) CO., LTD., Wuhan City (CN)

(21) Appl. No.: 13/557,283

(22) Filed: Jul. 25, 2012

(30) Foreign Application Priority Data
Nov. 11, 2011 (CN) 201110356861.X

(51) Int. Cl. G06F 1/16; H05K 7/14

(52) U.S. Cl. 361/679.02; 248/221.11

(57) ABSTRACT

A mounting apparatus for a PCI card includes an enclosure body, a mounting piece and a resisting member. The enclosure body comprises a bottom panel and a rear panel extending from the bottom panel. The mounting piece is used for attaching a first end of the PCI card on the rear panel. The resisting member is pivotally mounted to the enclosure body. The resisting member is rotated about an axis substantially perpendicular to the bottom panel to abut a second end of the PCI card to prevent the PCI card from moving along a direction substantially perpendicular to the bottom panel.

### BACKGROUND

1. Technical Field

The disclosure generally relates to mounting apparatuses, especially, to a mounting apparatus for a peripheral component interconnect (PCI) card.

2. Description of Related Art

PCI cards include network cards, monitor cards, and sound cards, that are used in a computer. The method for mounting PCI cards may involve screws and screwdrivers in a tedious endeavor often resulting in lost screws. A screw falling on a printed circuit board (PCB) can result in damage to the PCB.

Thus, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of an embodiment of a mounting apparatus for PCI cards.

FIG. 2 is similar to FIG. 1, but viewed from another aspect.

FIG. 3 is an isometric view of a mounting member of FIG. 1.

FIG. 4 is an assembled view of a cover panel, a mounting panel, and resisting member of FIG. 1.

FIG. 5 is an assembled view of an enclosure body, a PCB, a resisting member, and a PCI card FIG. 1, the resisting member being in a first position.

FIG. 6 is similar to FIG. 5, the resisting member being in a second position.

FIG. 7 is an assembled view of the mounting apparatus of FIG. 1.

FIG. 8 is an enlarged and partial isometric view of a portion VI of FIG. 7.

FIG. 9 is a cross-section view of FIG. 7 along lines VII-VII.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

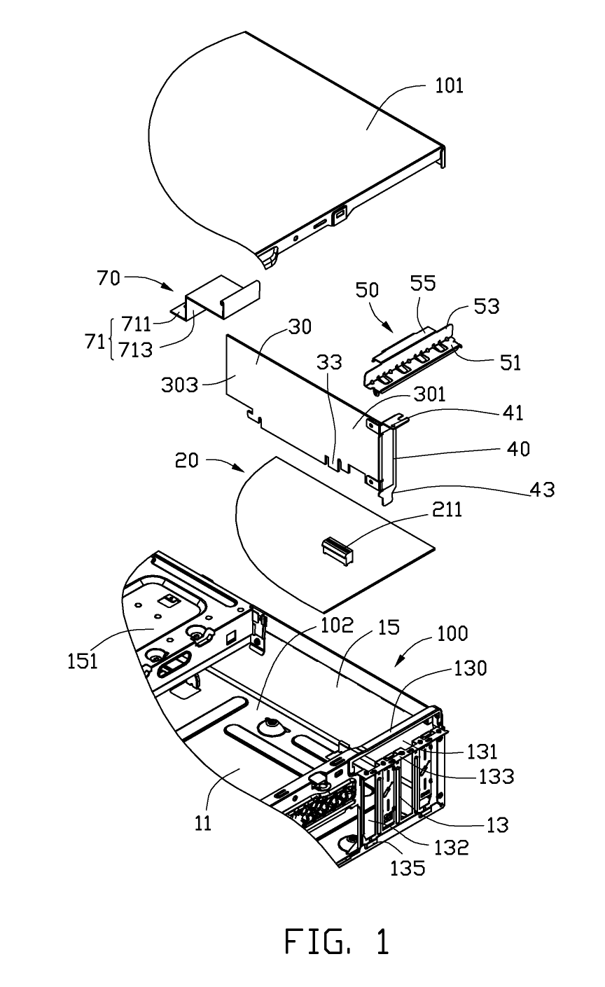

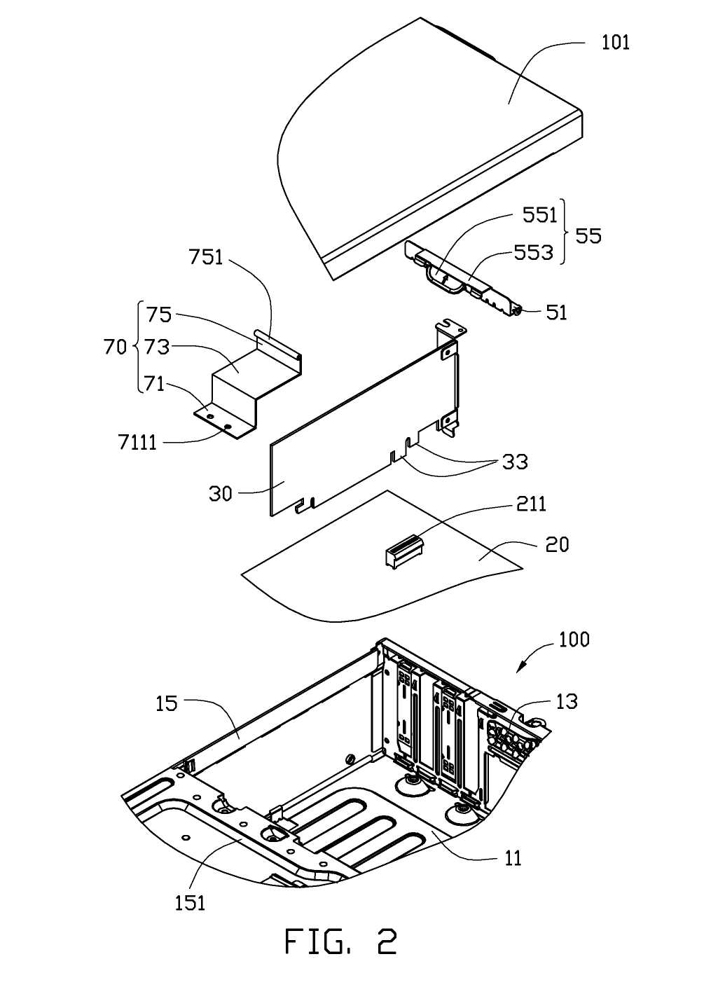

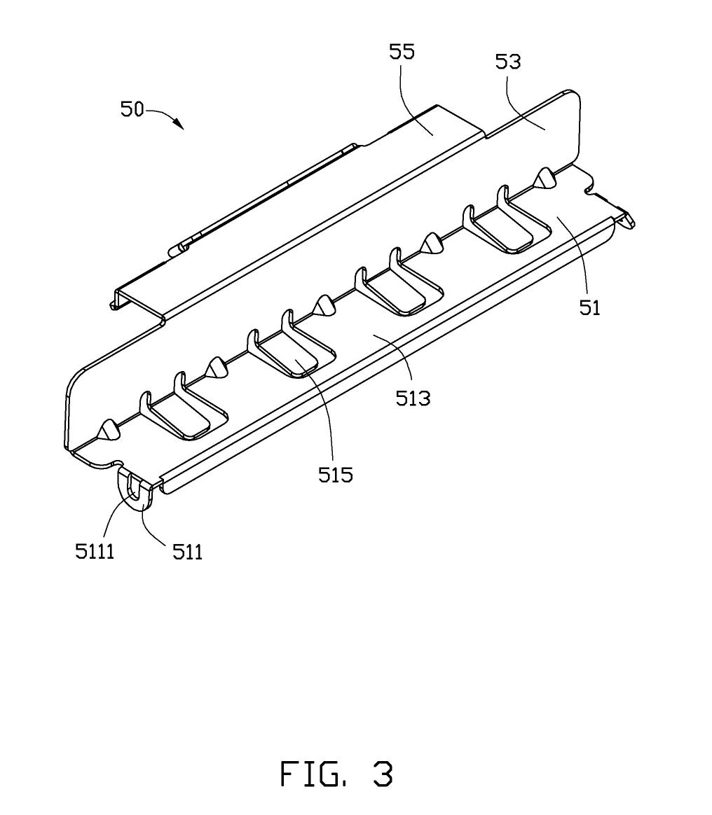

Referring to FIGS. 1 to 4, an embodiment of a mounting apparatus for one PCI card 30 is shown. The mounting apparatus includes an enclosure body 100, a cover panel 101, a mounting member 50, and a resisting member 70.

The PCI card 30 includes a first end 301 and a second end 303. The first end 301 is mounted to a mounting piece 40. The mounting piece 40 includes a mounting tab 41, a main portion 43 extending from the mounting tab 41, and an inserting portion 45 extending from the main portion 43. The PCI card 30 includes an inserting end 33 adjacent to the first end 301.

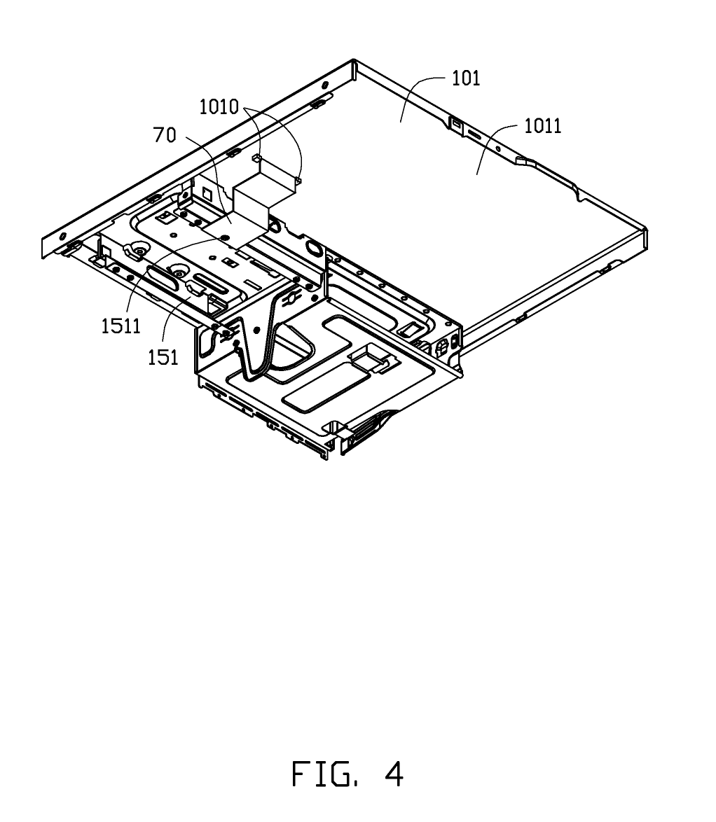

The enclosure body 100 includes a bottom panel 11, a rear panel 13 extending from the bottom panel 11, and a side panel 15 also extending from the bottom panel 11. The bottom panel 11 and the rear panel 13 are substantially perpendicular to the PCI card 30. A receiving opening 102 is defined in the enclosure body 100 and is surrounded by the side panel 15 and the rear panel 13. The rear panel 13 and the side panel 15 are substantially perpendicular to the bottom panel 11. The rear panel 13 defines a plurality of mounting slots 132 corresponding to the main portion 43 of the mounting piece 40. The rear panel 13 defines a receiving hole 135 corresponding to each mounting slot 132. The rear panel 13 defines a mounting opening 131. The rear panel 13 includes a blocking tab 133, extending from an edge of the mounting opening 131 and two pivot posts 1331, extending from opposite sides of the blocking tab 133. The rear panel 13 includes a side 130. A mounting bracket 151 is secured to the side panel 15. The mounting bracket 151 includes a pivot protrusion 1511 (shown in FIG. 4). The cover panel 101 includes a panel body 1011 and two positioning protrusions 1010, extending from an inner side of the panel body 1011. A PCB 20 is mounted on the bottom panel 11. The PCB 20 defines an insertion slot 211 corresponding to the inserting end 33 of the PCI card 30. The PCB 20 is substantially parallel to the bottom panel 11.

The mounting member 50 includes a pressing plate 51, a cover plate 53 extending from the pressing plate 51, and a handle portion 55 extending from the cover plate 53. The handle portion 55 includes an extending plate 553, extending from the cover plate 53, and a handle plate 551, extending from the extending plate 553. The pressing plate 51 includes a plate body 513, a plurality of pressing tabs 515 extending from the plate body 513, and two pivot tabs 511 extending from opposite sides of the plate body 513. Each pivot tab 511 defines a pivot hole 5111 corresponding to the pivot post 1331. The cover plate 53 is substantially perpendicular to the plate body 513. The extending plate 553 is substantially parallel to the plate body 513.

The resisting member 70 includes a mounting portion 71, a stopper panel 73, and a resisting panel 75 extending from the stopper panel 73. The mounting portion 71 includes a mounting panel 711 and an extending panel 713 extending from the mounting panel 711. The mounting panel 711 defines a mounting hole 7111 corresponding to the pivot protrusion 1511. The extending panel 713 is substantially perpendicular to both the mounting panel 711 and the stopper panel 73. The resisting panel 75 is substantially perpendicular to the stopper panel 73. The stopper panel 73 is substantially parallel to the bottom panel 11. The resisting panel 75 includes a contacting portion 751.

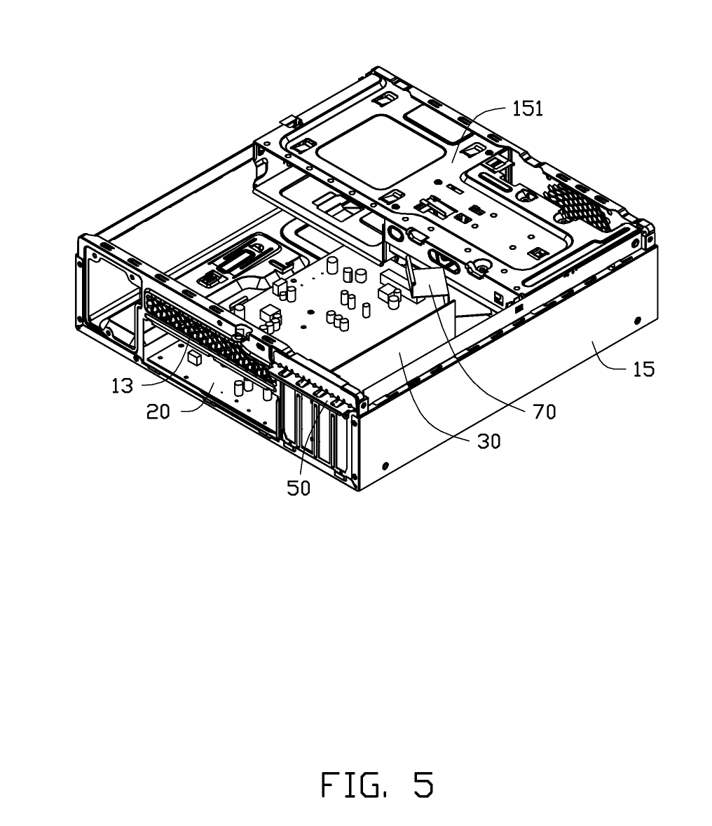

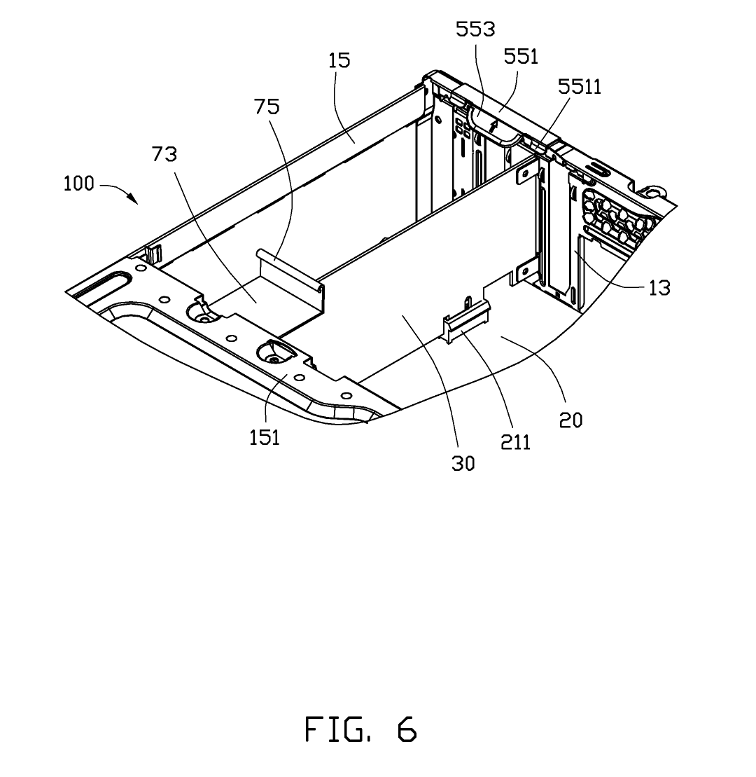

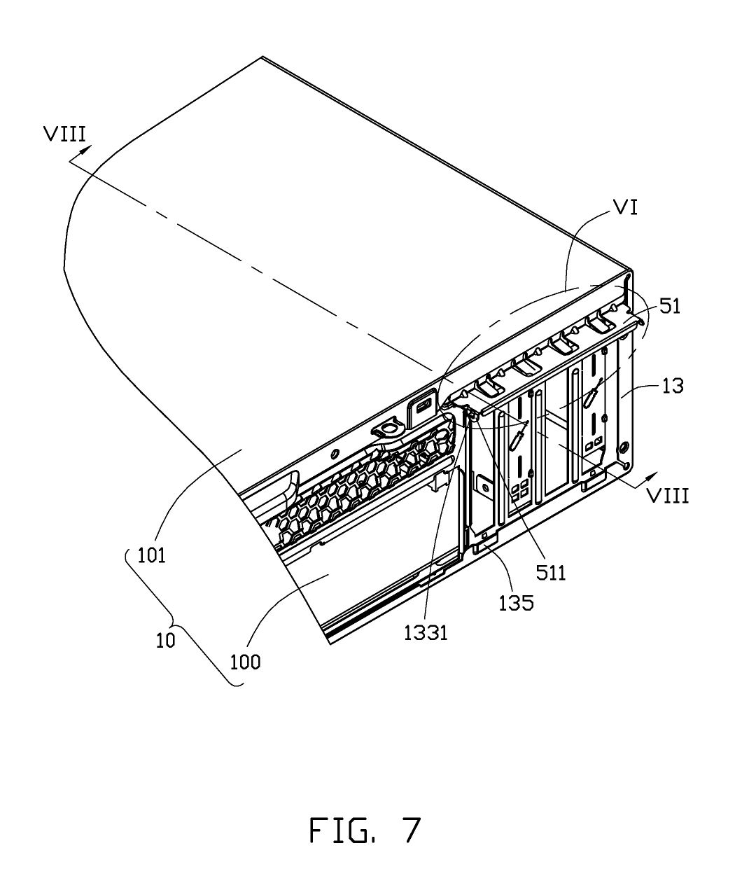

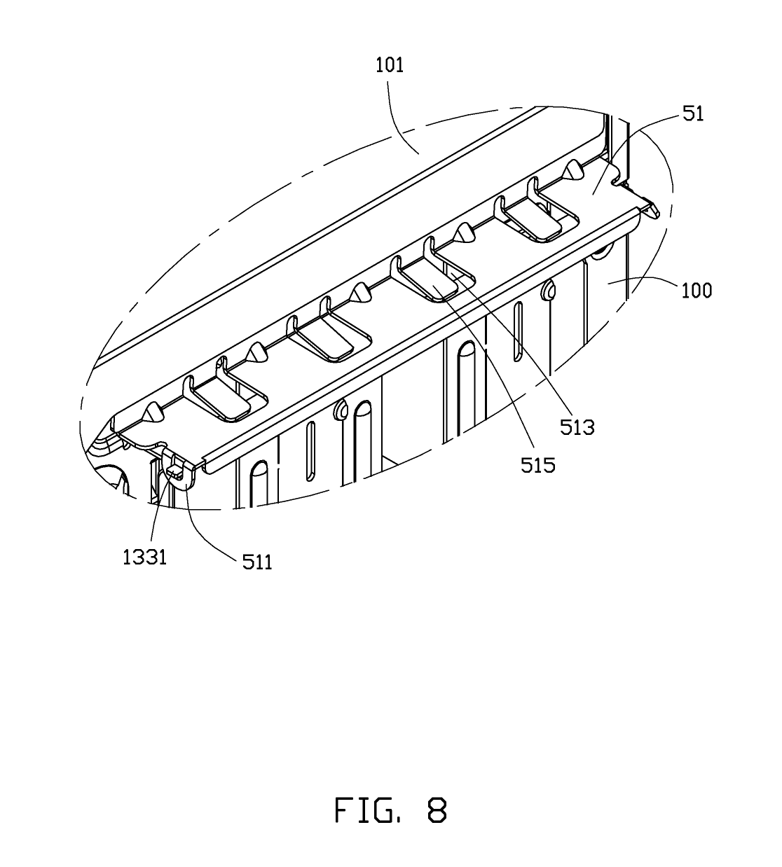

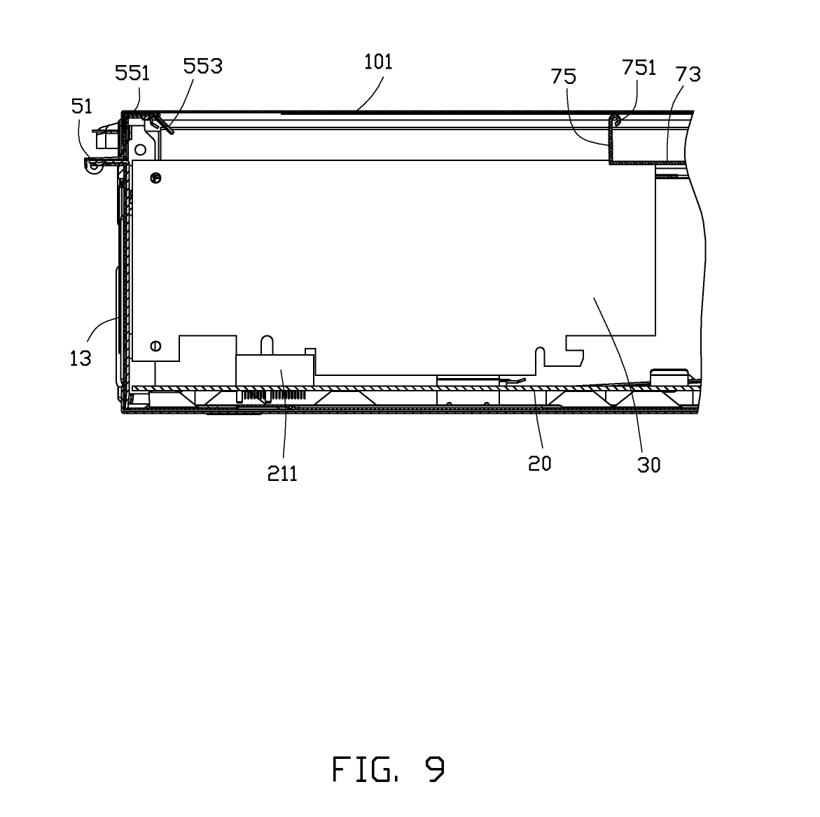

Referring to FIGS. 5 to 9, in assembly, the pivot holes 5111 of the two pivot tabs 511 of the mounting member 50 receive the pivot post 1331 of the rear panel 13. Thereby the mounting member 50 is pivotally mounted to the rear panel 13. The mounting hole 7111 of the resisting member 70 receives the pivot protrusion 1511 of the mounting bracket 151 to be pivotally mounted to the mounting bracket 151. The inserting end 33 of the PCI card 30 is received in insertion slot 211 of the PCB 20. At this time, the mounting tab 41 of the mounting piece 40 abuts the blocking tab 133. The inserting portion 45 is inserted in the receiving hole 135, and the main portion 43 covers the mounting slot 132. The resisting member 70 is rotated about an axis substantially perpendicular to the bottom panel 11 to enable the stopper panel 73, to abut the second end 303 of the PCI card 30. The mounting member 50 is rotated to enable the pressing tab 515 to press the mounting tab 41 and enable the extending plate 553 to contact the side 130 of the rear panel 13. At this time, the cover plate 53 covers the mounting opening 131 of the rear panel 13. Then, the cover panel 101 is mounted to the enclosure body 100 to cover the receiving opening 102. The panel body 1011 of the cover panel 101 abuts the contacting portion 751 of the resisting member 70 and the extending plate 553, thereby securing the PCI card 30 in the enclosure body 100. At this time, the contacting portion 751 is located between the two positioning protrusions 1010 which prevent lateral movement.

In disassembly, the cover panel 101 is removed away from the enclosure body 100. The resisting member 70 is rotated to enable the stopper panel 73 to disengage from the second end 303 of the PCI card 30. The mounting member 50 is rotated to enable the pressing tab 515 to move away from the mounting tab 41. Then, the PCI card 30 can be easily removed from the enclosure body 100.

It is to be understood, however, that even though numerous characteristics and advantages have been set forth in the foregoing description of preferred embodiments, together with details of the structures and functions of the preferred embodiments, the disclosure is illustrative only, and changes may be made in detail, especially in the matters of shape, size, and arrangement of parts within the principles of the disclosure to the full extent indicated by the broad general meaning of the terms in which the appended claims are expressed.

What is claimed is:

1. A mounting apparatus, for a PCI card, comprising:
an enclosure body, the enclosure body comprises a bottom panel and a rear panel extending from the bottom panel;
a mounting piece configured to attach of the PCI card on the rear panel; and
a resisting member pivotally mounted to the enclosure body; and the resisting member is configured to be rotated about an axis that is substantially perpendicular to the bottom panel, to abut the PCI card and to prevent the PCI card from moving along a direction that is substantially perpendicular to the bottom panel.

2. The mounting apparatus for a PCI card of claim 1, wherein the resisting member comprises a mounting panel, an extending panel extending from the mounting panel, and a stopper panel extending from the extending panel; the mounting panel is pivotally mounted to the enclosure body; and the stopper panel is substantially parallel to the bottom panel and configured to abut the second end to prevent the PCI card from moving along the direction.

3. The mounting apparatus for a PCI card of claim 2, wherein the mounting panel is substantially parallel to the stopper panel and defines a mounting hole; and the enclosure body comprises a pivot protrusion pivotally received in the mounting hole.

4. The mounting apparatus for a PCI card of claim 2, wherein the extending panel is substantially perpendicular to the stopper panel.

5. The mounting apparatus for a PCI card of claim 2, further comprising a cover panel substantially parallel to the bottom panel, wherein the resisting member further comprises a resisting panel extending from the stopper panel; a receiving opening is defined in the enclosure body; and the cover panel is configured to cover the receiving opening to abut the resisting panel.

6. The mounting apparatus for a PCI card of claim 5, wherein the cover panel comprises a panel body and two positioning protrusions; the resisting panel comprises a contacting portion, the panel body is configured to abut the contacting portion; and the contacting portion is configured to be located between the two positioning protrusions, thereby preventing the resisting member from rotating.

7. The mounting apparatus for a PCI card of claim 5, wherein the resisting panel is substantially perpendicular to the stopper panel.

8. The mounting apparatus for a PCI card of claim 5, further comprising a mounting member; wherein the mounting member is pivotally mounted to the rear panel; the mounting member is configured to abut the mounting piece to prevent the mounting piece from moving along the direction; and the cover panel is configured to press the mounting member to abut the mounting piece, when the cover panel covers the receiving opening.

9. The mounting apparatus for a PCI card of claim 8, wherein the mounting member comprises a pressing plate, a cover plate extending from the pressing plate, and a handle portion extending from the cover plate; the rear panel comprises a blocking tab; the mounting piece is configured to be placed on the blocking tab; the pressing plate is pivotally mounted to the blocking tab and configured to press the mounting piece on the blocking tab; and the cover panel is configured to press the handle portion.

10. A PCI card assembly, comprising:
an enclosure body, the enclosure body comprises a bottom panel and a rear panel extending from the bottom panel;
a PCI card, the PCI card is substantially perpendicular to the bottom panel, and the PCI card comprises a first end and a second end;
a mounting piece attached the first end of the PCI card, the mounting piece is mounted on the rear panel; and
a resisting member pivotally mounted to the enclosure body; the resisting member abuts the second end to prevent the PCI card from moving along a direction that is substantially perpendicular to the bottom panel; and the resisting member is configured to be rotated about an axis substantially parallel to the PCI card to disengage from the second end.

11. The PCI card assembly of claim 10, wherein the resisting member comprises a mounting panel, an extending panel extending from the mounting panel, and a stopper panel extending from the extending panel; the mounting panel is pivotally mounted to the enclosure body; and the stopper panel is substantially parallel to the bottom panel and abuts the second end to prevent the PCI card from moving along the direction.

12. The PCI card assembly of claim 11, wherein the mounting panel is substantially parallel to the stopper panel and defines a mounting hole; and the enclosure body comprises a pivot protrusion pivotally received in the mounting hole.

13. The PCI card assembly of claim 11, wherein the extending panel is substantially perpendicular to the stopper panel.

14. The PCI card assembly of claim 11, further comprising a cover panel substantially parallel to the bottom panel, wherein the resisting member further comprises a resisting panel extending from the stopper panel; a receiving opening is defined in the enclosure body; and the cover panel covers the receiving opening to abut the resisting panel.

15. The PCI card assembly of claim 14, wherein the cover panel comprises a panel body and two positioning protrusions; the resisting panel comprises a contacting portion, the panel body abuts the contacting portion; and the contacting portion is located between the two positioning protrusions, thereby preventing the resisting member from rotating.

16. The PCI card assembly of claim 14, wherein the resisting panel is substantially perpendicular to the stopper panel.

17. The PCI card assembly of claim 14, further comprising a mounting member; wherein the mounting member is pivotally mounted to the rear panel; the mounting member abuts the mounting piece to prevent the mounting piece from moving along the direction; and the cover panel presses the mounting member to abut the mounting piece.

18. The PCI card assembly of claim 17, wherein the mounting member comprises a pressing plate, a cover plate extending from the pressing plate, and a handle portion extending from the cover plate; the rear panel comprises a blocking tab; the mounting piece is placed on the blocking tab; the pressing plate is pivotally mounted to the blocking tab and presses the mounting piece on the blocking tab; and the cover panel presses the handle portion.
